(19) United States
(12) Patent Application Publication
(10) Pub. No.: US 2024/0274410 A1
(43) Pub. Date: Aug. 15, 2024

(54) PLASMA-RESISTANT GLASS, CHAMBER INTERIOR PARTS FOR SEMICONDUCTOR MANUFACTURING PROCESS, AND METHODS FOR MANUFACTURING SAME

(71) Applicant: IONES CO., LTD., Anseong-si (KR)

(72) Inventors: Dae Gun Kim, Osan-si (KR); Hye Won Seok, Osan-si (KR); KyungMin Lee, Hwaseong-si (KR); Hye In Na, Hwaseong-si (KR); Mun ki Lee, Suwon-si (KR)

(73) Assignee: Hansol IONES Co., Ltd., Anseong-si (KR)

(21) Appl. No.: 18/566,335

(22) PCT Filed: May 13, 2022
(86) PCT No.: PCT/KR2022/006893

§ 371 Date: Jan. 25, 2024

(30) Foreign Application Priority Data
Jun. 4, 2021 (KR) 10-2021-0072961

(51) Int. Cl. H01J 37/32; C03C 3/085; C03C 4/20; H01J 9/24

(52) U.S. Cl. CPC H01J 37/32467; C03C 3/085; C03C 4/20; H01J 37/32495; C03C 2203/10; C03C 2203/52; H01J 9/245; H01J 2237/0213

(57) ABSTRACT

The present invention relates to a plasma-resistant glass, chamber interior parts for a semiconductor manufacturing process, and methods for manufacturing same, and specifically, to a plasma-resistant glass and a method for manufacturing same, wherein the content of components of the plasma-resistant glass can be controlled to reduce the thermal expansion coefficient of the glass and thereby prevent the glass from being damaged due to thermal shock when used at a high-temperature.

### TECHNICAL FIELD

The present invention claims priority to Korean Patent Application No. 10-2021-0072961, filed on Jun. 4, 2021, the invention of which is incorporated by reference herein in its entirety. The present invention relates to a plasma-resistant glass, chamber interior parts for a semiconductor manufacturing process, and methods for manufacturing the same, and specifically, a plasma-resistant glass and a method for manufacturing same, wherein the content of components of the plasma-resistant glass can be controlled to reduce a thermal expansion coefficient of the glass, thereby preventing the glass from being damaged due to thermal shock when used at high temperatures.

### BACKGROUND ART

A plasma etching process is applied when semiconductors and/or displays are manufactured. Recently, with the application of a nano-process, the difficulty of etching is increased, and oxide-based ceramics such as alumina (Al₂O₃) and yttria (Y₂O₃), which have corrosion resistance, are mainly used for internal parts of process chambers exposed to a high-density plasma environment.

When a polycrystalline material is exposed to the high-density plasma etching environment using a fluorine-based gas for a long time, particles are eliminated due to local erosion, resulting in an increase in a probability of generating contaminant particles. This causes defects in semiconductors/displays and adversely affects production yield.

### SUMMARY OF INVENTION

### Technical Problem

The present invention is directed to a plasma-resistant glass, chamber interior parts for a semiconductor manufacturing process, and methods of manufacturing the same, wherein resistance is excellent due to plasma inside chambers used in a semiconductor manufacturing process, and thermal resistance is excellent in a high-temperature condition, thereby preventing damage to parts used inside the chambers.

However, the object of the present invention is not limited to the above-described object, and other objects that are not mentioned will be able to be clearly understood by those skilled in the art from the following description.

### Solution to Problem

One embodiment of the present invention provides plasma-resistant glass containing 55 mol % or more to 70 mol % or less of SiO₂, 5 mol % or more to 20 mol % or less of Al₂O₃, and 29 mol % or more to 35 mol % or less of MgO.

One embodiment of the present invention provides the chamber interior parts for the semiconductor manufacturing process, which are made of the plasma-resistant glass.

One embodiment of the present invention provides a method of manufacturing plasma-resistant glass including an operation of melting a composition containing 55 mol % or more to 70 mol % or less of SiO₂, 5 mol % or more to 20 mol % or less of Al₂O₃, and 29 mol % or more to 35 mol % or less of MgO, and an operation of rapidly cooling the molten composition.

One embodiment of the present invention provides a method of manufacturing the chamber interior parts for the semiconductor manufacturing process including an operation of melting the plasma-resistant glass, an operation of injecting the molten plasma-resistant glass into a mold, and an operation of annealing the injected plasma-resistant glass.

### Advantageous Effects

The plasma-resistant glass according to one embodiment of the present invention can provide the low thermal expansion coefficient characteristic to prevent damage due to thermal shock under the high temperature atmosphere.

The chamber interior parts for the semiconductor manufacturing process according to an embodiment of the present invention can increase the use time in the semiconductor manufacturing process by implementing the low etching rate for plasma, and improving durability by preventing damage to parts due to thermal shock.

The method of manufacturing the plasma-resistant glass according to one embodiment of the present invention can easily manufacture the plasma-resistant glass and prevent damage due to thermal shock under the high temperature atmosphere.

The method of manufacturing the chamber interior parts for the semiconductor manufacturing process according to one embodiment of the present invention can manufacture parts with various shapes and prevent damage due to thermal shock under the high temperature atmosphere.

The effects of the present invention are not limited thereto, and other effects that are not mentioned will be able to be clearly understood to those skilled in the art from the specification and the accompanying drawings of this application.

### BRIEF DESCRIPTION OF DRAWINGS

FIG. 1 is a flowchart of a method of manufacturing plasma-resistant glass according to one embodiment of the present invention.

FIG. 2 is a flowchart of a method of manufacturing chamber interior parts for a semiconductor manufacturing process according to one embodiment of the present invention.

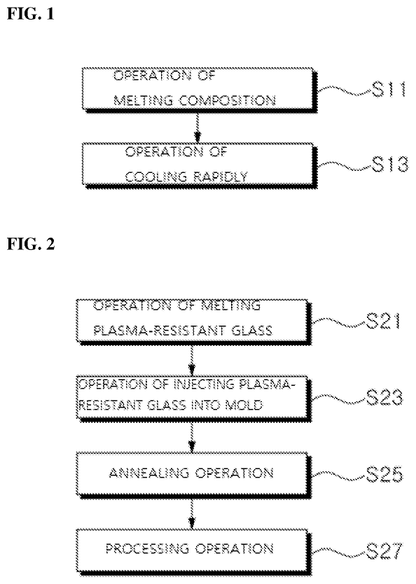

### DESCRIPTION OF REFERENCE NUMERALS

S11: operation of melting composition S13: operation of cooling rapidly
S21: operation of melting plasma-resistant glass S23: operation of injecting plasma-resistant glass into mold
S25: annealing operation S27: processing operation

### DESCRIPTION OF EMBODIMENTS

Throughout the specification, when a certain portion is described as “including” a certain component, it means further including another component rather than precluding another component unless especially stated otherwise.

Throughout the specification, when a certain member is described as being positioned “on” another member, it includes not only a case in which the certain member comes into contact with another member but also a case in which still another member is present between the two members.

Throughout the specification, the term “A and/or B” means “A and B, or A or B.”

Hereinafter, the present invention will be described in more detail.

One embodiment of the present invention provides plasma-resistant glass containing 55 mol % or more to 70 mol % or less of SiO₂, 5 mol % or more to 20 mol % or less of Al₂O₃, and 29 mol % or more to 35 mol % or less of MgO.

The plasma-resistant glass according to one embodiment of the present invention can provide the low thermal expansion coefficient characteristic to prevent damage due to thermal shock under the high temperature atmosphere.

According to one embodiment of the present invention, the plasma-resistant glass contains 55 mol % or more and 70 mol % or less of SiO₂. Specifically, the plasma-resistant glass may contain 56 mol % or more and 69 mol % or less, 57 mol % or more and 68 mol % or less, 58 mol % or more and 67 mol % or less, 59 mol % or more and 66 mol % or less, 60 mol % or more and 65 mol %, 61 mol % or more and 64 mol % or less, or 62 mol % or more and 63 mol % or less of SiO₂. As described above, by containing SiO₂ and controlling the content of SiO₂ in the above-described range, it is possible to secure the basic physical properties of the plasma-resistant glass, improve durability, and reduce the manufacturing costs of parts by facilitating the processing of the plasma-resistant glass.

According to one embodiment of the present invention, the plasma-resistant glass contains 5 mol % or more and 20 mol % or less of Al₂O₃. Specifically, the plasma-resistant glass may contain 6 mol % or more and 19 mol % or less, 7 mol % or more and 18 mol % or less, 8 mol % or more and 17 mol % or less, 9 mol % or more and 16 mol % or less, 10 mol % or more and 15 mol %, 11 mol % or more and 14 mol % or less, or 12 mol % or more and 13 mol % or less of Al₂O₃. As described above, by containing Al₂O₃ and controlling the content of Al₂O₃ in the above-described range, it is possible to prevent outgassing, suppress the generation of particles, and improve the wear resistance of chamber interior parts for a semiconductor manufacturing process.

According to one embodiment of the present invention, the plasma-resistant glass contains 29 mol % or more and 35 mol % or less of MgO. Specifically, the plasma-resistant glass may contain 29 mol % or more and 35 mol % or less, 30 mol % or more and 34 mol % or less, 31 mol % or more and 33 mol % or less, 32 mol % or more and 33 mol % or less, or 31 mol % or more and 32 mol % of MgO. As described above, by containing MgO and controlling the content of MgO in the above-described range to implement a lower thermal expansion coefficient of glass and a lower glass transition temperature, it is possible to minimize thermal shock at high temperatures and improve durability of the chamber interior parts for the semiconductor manufacturing process.

According to one embodiment of the present invention, a molar ratio of SiO₂ and Al₂O₃ may be in a range of 6:1 to 2.5:1. Specifically, the molar ratio of SiO₂ and Al₂O₃ may be in a range of 5.9:1 to 2.6:1, 5.8:1 to 2.7:1, 5.7:1 to 2.8:1, 5.6:1 to 2.9:1, 5.5:1 to 3.0:1, 5.4:1 to 3.1:1, 5.3:1 to 3.2:1, 5.2:1 to 3.3:1, 5.1:1 to 3.4:1, 5.0:1 to 3.5:1, 4.9:1 to 3.6:1, 4.8:1 to 3.7:1, 4.7:1 to 3.8:1, 4.6:1 to 3.9:1, 4.5:1 to 4.0:1, 4.4:1 to 4.1:1, or 4.3:1 to 4.2:1. By controlling the molar ratio of SiO₂ and Al₂O₃ in the above-described range, it is possible to improve the wear resistance of the plasma-resistant glass and at the same time, easily achieve processability.

According to one embodiment of the present invention, a molar ratio of SiO₂ and MgO may be in a range of 2:1 to 1.4:1. Specifically, the molar ratio of SiO₂ and MgO may be in a range of 2:1 to 1.4:1, 1.9:1 to 1.5:1, 1.8:1 to 1.6:1, 1.7:1 to 1.6:1, or 1.8:1 to 1.7:1. By controlling the molar ratio of the SiO₂ and the MgO in the above-described range, it is possible to improve the durability and reliability of the plasma-resistant glass and at the same time, improve durability against thermal shock at high temperatures.

According to one embodiment of the present invention, a molar ratio of MgO and Al₂O₃ may be in a range of 3.5:1 to 1.5:1. Specifically, the molar ratio of MgO and Al₂O₃ may be in a range of 3.4:1 to 1.6:1, 3.3:1 to 1.7:1, 3.2:1 to 1.8:1, 3.1:1 to 1.9:1, 3.0:1 to 2.0:1, 2.9:1 to 2.1:1, 2.8:1 to 2.2:1, 2.7:1 to 2.3:1, or 2.6:1 to 2.4:1. By controlling the molar ratio of MgO and Al₂O₃ in the above-described range, it is possible to minimize thermal shock at high temperatures and improve the durability of the chamber interior parts for the semiconductor manufacturing process.

According to one embodiment of the present invention, a glass transition temperature of the plasma-resistant glass may be 750° C. or higher and 850° C. or lower. Specifically, the glass transition temperature of the plasma-resistant glass may be in a range of 760° C. or higher and 840° C. or lower, 770° C. or higher and 830° C. or lower, 780° C. or higher and 820° C. or lower, or 790° C. or higher and 810° C. or lower. By controlling the glass transition temperature of the plasma-resistant glass in the above-described range, it is possible to minimize thermal shock at high temperatures of the chamber interior parts for the semiconductor manufacturing process and improve durability.

According to one embodiment of the present invention, the thermal expansion coefficient of the plasma-resistant glass may be in a range of 4.0×10⁻⁶ m/(m° C.) or more and 6.0×10⁻⁶ m/(m° C.) or less. Specifically, the thermal expansion coefficient of the plasma-resistant glass may be 4.1×10⁻⁶ m/(m° C.) or more and 5.9×10⁻⁶ m/(m° C.) or less, 4.2×10⁻⁶ m/(m° C.) or more and 5.8×10⁻⁶ m/(m° C.) or less, 4.3×10⁻⁶ m/(m° C.) or more and 5.7×10⁻⁶ m/(m° C.) or less, 4.4×10⁻⁶ m/(m° C.) more and 5.6×10⁻⁶ m/(m° C.) or less, 4.5×10⁻⁶ m/(m° C.) or more and 5.5×10⁻⁶ m/(m° C.) or less, 4.6×10⁻⁶ m/(m° C.) or more and 5.4×10⁻⁶ m/(m° C.) or less, 4.7×10⁻⁶ m/(m° C.) or more and 5.3×10⁻⁶ m/(m° C.) or less, 4.8×10⁻⁶ m/(m° C.) or more and 5.2×10⁻⁶ m/(m° C.) or less, or 4.9×10⁻⁶ m/(m° C.) or more and 5.1×10⁻⁶ m/(m° C.) or less. By controlling the thermal expansion coefficient of the plasma-resistant glass in the above-described range, it is possible to prevent damage to parts due to thermal shock, thereby improving durability.

According to one embodiment of the present invention, an etching rate of the plasma-resistant glass by mixed plasma of fluorine and argon (Ar) may be 18 nm/min or less. Specifically, the etching rate by the mixed plasma of fluorine and argon may be more than 0 nm/min and 17 nm/min or less, 1 nm/min or more and 16 nm/min or less, more than 2 nm/min and 15 nm/min or less, 3 nm/min or more and 14 nm/min or less, 4 nm/min or more and 13 nm/min or less, 5 nm/min or more and 12 nm/min or less, 6 nm/min or more and 11 nm/min or less, or 7 nm/min more and 10 nm/min or less. By implementing the etching rate by the mixed plasma of fluorine and argon (Ar) in the above-described range to implement the lower etching rate for plasma of the chamber interior parts for the semiconductor manufacturing process, it is possible to increase the use time in the semiconductor manufacturing process.

One embodiment of the present invention provides the chamber interior parts for the semiconductor manufacturing process, which are made of the plasma-resistant glass.

The chamber interior parts for the semiconductor manufacturing process according to an embodiment of the present invention can increase the use time in the semiconductor manufacturing process by implementing the low etching rate for plasma, and improving durability by preventing damage to parts due to thermal shock.

According to one embodiment of the present invention, the interior parts may be any one of a focus ring, an edge ring, a cover ring, a ring shower, an insulator, an EPD window, an electrode, a view port, an inner shutter, an electro static chuck, a heater, a chamber liner, a shower head, a chemical vapor deposition (CVD) boat, a wall liner, a shield, a cold pad, a source head, an outer liner, a deposition shield, an upper liner, an exhaust plate, and a mask frame. It is possible to extend the user time by improving the resistance against plasma in the semiconductor manufacturing process using the above-described parts as the internal parts, thereby minimizing the cost required for manufacturing the semiconductor.

One embodiment of the present invention provides a method of manufacturing plasma-resistance glass including an operation of melting a composition containing 55 mol % or more to 70 mol % or less of SiO₂, 5 mol % or more to 20 mol % or less of Al₂O₃, and 29 mol % or more to 35 mol % or less of MgO (S11), and an operation of rapidly cooling the molten composition (S13).

The method of manufacturing the plasma-resistant glass according to one embodiment of the present invention can easily manufacture the plasma-resistant glass and prevent damage due to thermal shock under the high temperature atmosphere.

In the method for manufacturing the plasma-resistant glass according to one embodiment of the present invention, contents overlapping the plasma-resistant glass is omitted.

According to one embodiment of the present invention, the method of manufacturing the plasma-resistant glass includes an operation of melting a composition containing 55 mol % or more to 70 mol % or less of SiO₂, 5 mol % or more to 20 mol % or less of Al₂O₃, and 29 mol % or more to 35 mol % or less of MgO (S11). By controlling the components of the plasma-resistant glass and controlling the content of the components from the above description, it is possible to prevent damage due to thermal shock under the high-temperature atmosphere of the plasma-resistant glass.

According to one embodiment of the present invention, the method for manufacturing the plasma-resistant glass includes the operation of rapidly cooling the molten composition (S13). By including the operation of rapidly cooling the molten composition as described above, melting in the process of manufacturing the chamber interior parts for the semiconductor manufacturing process may be easily performed.

According to one embodiment of the present invention, a temperature of the operation of cooling rapidly may be room temperature. By controlling the temperature of the operation of cooling rapidly in the above-described range, crystals of the plasma-resistant glass may be controlled, and melting in the process of manufacturing the chamber interior parts for the semiconductor manufacturing process may be easily performed.

According to one embodiment of the present invention, a melting temperature in the operation of melting the composition may be in a range of 1400° C. or higher and 1700° C. or lower. Specifically, the melting temperature in the operation of melting the composition may be in a range of 1400° C. or higher and 1700° C. or lower, 1450° C. or higher and 1650° C. or lower, or 1500° C. or higher and 1600° C. or lower. By controlling the melting temperature in the operation of melting the composition in the above-described range, it is possible to improve the workability of the process of manufacturing the plasma-resistant glass by controlling the viscosity of the composition.

One embodiment of the present invention provides the method of manufacturing the chamber interior parts for the semiconductor manufacturing process including an operation of melting the plasma-resistant glass (S21), an operation of injecting the molten plasma-resistant glass into a mold (S23), and an operation of annealing the injected plasma-resistant glass (S25).

The method of manufacturing the chamber interior parts for the semiconductor manufacturing process according to one embodiment of the present invention can manufacture parts with various shapes and prevent damage due to thermal shock under the high temperature atmosphere.

According to one embodiment of the present invention, the method of manufacturing the chamber interior parts for the semiconductor manufacturing process includes the operation of melting the plasma-resistant glass (S21). By including the operation of melting the plasma-resistant glass as described above, it is possible to improve the workability of the process of manufacturing the chamber interior parts for the semiconductor manufacturing process and at the same time, by injecting the molten metal in which the plasma-resistant glass is melted into the mold, the glass may be molded into various shapes.

According to one embodiment of the present invention, the method of manufacturing the chamber interior parts for the semiconductor manufacturing process includes the operation of injecting the molten plasma-resistant glass into the mold (S23). As described above, parts in various shapes may be manufactured by injecting the molten plasma-resistant glass into the mold.

According to one embodiment of the present invention, the mold may have any one form of a focus ring, an edge ring, a cover ring, a ring shower, an insulator, an EPD window, an electrode, a view port, an inner shutter, an electro static chuck, a heater, a chamber liner, a shower head, a chemical vapor deposition (CVD) boat, a wall liner, a shield, a cold pad, a source head, an outer liner, a deposition shield, an upper liner, an exhaust plate, and a mask frame. As described above, by implementing various shapes of the mold to easily implement the shapes of the parts, it is possible to reduce the manufacturing time.

According to one embodiment of the present invention, the method of manufacturing the chamber interior parts for the semiconductor manufacturing process includes the operation of annealing the injected plasma-resistant glass (S25). By including the operation of annealing the injected plasma-resistant glass as described above, it is possible to minimize the stress due to heat generated in the parts manufactured by being injected into the mold, thereby improving the durability of the parts and minimizing thermal shock at high temperatures.

According to one embodiment of the present invention, a melting temperature in the operation of melting the plasma-resistant glass may be in a range of 1400° C. or higher and 1700° C. or lower. Specifically, the melting temperature in the operation of melting the plasma-resistant glass may be in a range of 1450° C. or more and 1650° C. or less, or 1500° C. or more and 1600° C. or less. By controlling the melting temperature in the operation of melting the plasma-resistant glass in the above-described range to control the viscosity of the molten plasma-resistant glass, it is possible to improve workability.

According to one embodiment of the present invention, a temperature of the annealing operation may be 400° C. or more and 900° C. or less. Specifically, the temperature of the annealing operation may be in a range of 430° C. or higher and 890° C. or lower, 450° C. or higher and 880° C. or lower, 470° C. or higher and 870° C. or lower, 500° C. or higher and 860° C. or lower, 550° C. or higher and 850° C. or lower, 560° C. or higher and 840° C. or lower, 570° C. or higher and 830° C. or lower, 580° C. or higher and 820° C. or lower, 590° C. or higher and 810° C. or lower, 600° C. higher and 800° C. or lower, 610° C. or higher and 790° C. or lower, 620° C. or higher and 780° C. or lower, 630° C. or higher and 770° C. or lower, 640° C. or higher and 760° C. or lower, 650° C. or higher and 750° C. or lower, 660° C. or higher and 740° C. or lower, 670° C. or higher and 730° C. or lower, 680° C. or higher and 720° C. or lower, or 690° C. or higher and 710° C. or lower. By controlling the temperature of the annealing operation in the above-described range, it is possible to reduce the stress due to the heat formed in the chamber interior parts for the semiconductor manufacturing process and minimize thermal shock at high temperatures, thereby improving the durability of the parts.

According to one embodiment of the present invention, the method may include an operation of processing a precursor of the chamber interior parts for the semiconductor manufacturing process manufactured using the annealed plasma-resistant glass (S27). As described above, sophisticated parts may be manufactured by processing the precursor of the chamber interior parts for the semiconductor manufacturing process.

Hereinafter, in order to specifically describe the present invention, the present invention will be described in detail through examples. However, the examples according to the present invention may be modified into various other forms, and the scope of the present invention should not be construed as being limited to the examples to be described below. The examples in the specification are provided to more completely describe the present invention to those skilled in the art.

### Example 1

A composition containing 59.27 mol % SiO₂, 10.31 mol % Al₂O₃, and 30.43 mol % MgO. Specifically, the total amount of chemical components with a weight of 600 g was provided, and the composition was mixed for about 1 hour by a zirconia ball milling method. In other words, the composition was dry mixed with 600 g (composition):1800 g (zirconia ball) (weight ratio 1:3), and then dried for 24 hours. Thereafter, the temperature of the dried composition was increased at a rate of 10° C./min until reaching a temperature of 1400° C. using a super kanthal furnace and maintained at a temperature of 1400° C. for about 2 hours and 30 minutes.

The molten composition was rapidly cooled to room temperature to manufacture plasma-resistant glass.

### Example 2

The plasma-resistant glass was manufactured in the same manner as in Example 1, except that a composition containing 52.50 mol % of SiO₂, 15.00 mol % of Al₂O₃, and 32.50 mol % of MgO as the component and content of the composition, was manufactured and used.

### Comparative Example 1

The plasma-resistant glass was manufactured in the same manner as in Example 1, except that a composition containing 52.10 mol % of SiO₂, 11.94 mol % of Al₂O₃, and 35.97 mol % of MgO as the component and content of the composition was manufactured and used.

### Experimental Example 1: Measurement of Glass Transition Temperature and Thermal Expansion Coefficient

For the plasma-resistant glasses of Examples 1 and 2 and Comparative Example 1, the thermal expansion coefficient (α=100 to 300° C.) and the glass transition temperature (Tg) were measured at a heating rate of 10° C. under a N₂−4 wt % H₂ mixed gas atmosphere using a dilatometer (DIL 402 C, NETZSCH, Germany) and are summarized in Table 1 below.

### Experimental Example 2: Measurement of Etching Rate

A portion exposed after masking both side surfaces of the plasma-resistant glass of Examples 1 and 2 and Comparative Example 1 at 3 mm intervals was etched in a CF₄ mixed gas environment for about 1 hour using ICP-Etcher equipment.
RF power (W): 600
RF power, bias (W): 150
CF₄ (SCCM): 30
Ar (SCCM): 10
O₂ (SCCM): 5
Pressure (mTorr): 10
time (min): 60

After removing the masking of the completely etched plasma-resistant glass, an Average value after measuring a step before and after etching three times using a surfcorder ET3000 (Kosaka Laboratory Ltd., Japan) is summarized in Table 1 below.

TABLE 1

| | | thermal expansion | |
|---|---|---|---|
| | glass transition | coefficient | |
| | temperature | (CTE, ×10⁻⁶ | etching rate |
| | (Tg, ° C.) | m/(m° C.)) | (nm/min) |
| Example 1 | 804.7 | 4.34 | 10.09 |
| Example 2 | 806 | 4.842 | 12.50 |
| Comparative | 794.4 | 5.842 | 7.14 |
| Example 1 | | | |

Referring to Table 1, in Examples 1 and 2, it could be seen that the glass transition temperature was implemented to 810° C. or lower and at the same time, the etching rate was implemented to 16 nm/min or less to implement a low melting point and at the same time, a low etching rate, thereby improving workability and durability, and it could be seen that it was possible to prevent thermal shock at high temperatures by implementing the lower thermal expansion coefficient.

In contrast, in Comparative Example 1, it could be seen that since each of the contents of SiO₂, Al₂O₃, and MgO was not satisfied, the etching rate and the glass transition temperature were implemented low but the thermal expansion coefficient was implemented high, making it vulnerable to thermal shock at high temperatures.

Therefore, in one embodiment of the present invention, by satisfying the contents of SiO₂, Al₂O₃, and MgO of the plasma-resistant glass, it is possible to implement the lower etching rate and glass transition temperature and at the same time, implement the lower thermal expansion coefficient, thereby preventing thermal shock at high temperatures.

Although the present invention has been described above by the limited embodiments, the present invention is not limited thereto, and it goes without saying that various modifications and changes are possible by those skilled in the art to which the present invention pertains within the technical spirit of the present invention and the equivalent scope of the claims to be described below.

1. A plasma-resistant glass comprising:
SiO₂ in an amount ranging from 55 mol % to 70 mol %,
Al₂O₃ in an amount ranging from 5 mol % to 20 mol %, and
MgO in an amount ranging from 29 mol % to 35 mol %.

2. The plasma-resistant glass of claim 1, wherein a molar ratio of SiO₂ and Al₂O₃ is in a range of from 6:1 to 2.5:1.

3. The plasma-resistant glass of claim 1, wherein a molar ratio of SiO₂ and MgO is in a range of from 2:1 to 1.4:1.

4. The plasma-resistant glass of claim 1, wherein a molar ratio of MgO and Al₂O₃ is in a range of from 3.5:1 to 1.5:1.

5. The plasma-resistant glass of claim 1, wherein a glass transition temperature of the plasma-resistant glass is in a range of from 750° C. to 850° C.

6. The plasma-resistant glass of claim 1, wherein a thermal expansion coefficient of the plasma-resistant glass is in a range of from 4.0×10⁻⁶ m/(m° C.) to 6.0×10⁻⁶ m/(m° C.).

7. The plasma-resistant glass of claim 1, wherein an etching rate of the plasma-resistant glass by mixed plasma of fluorine and argon (Ar) is 18 nm/min or less.

8. Chamber interior parts for a semiconductor manufacturing method, comprising the plasma-resistant glass of claim 1.

9. The chamber interior parts of claim 8, wherein the chamber interior parts are any one of a focus ring, an edge ring, a cover ring, a ring shower, an insulator, an EPD window, an electrode, a view port, an inner shutter, an electro static chuck, a heater, a chamber liner, a shower head, a chemical vapor deposition (CVD) boat, a wall liner, a shield, a cold pad, a source head, an outer liner, a deposition shield, an upper liner, an exhaust plate, or a mask frame.

10. A method of manufacturing plasma-resistant glass, comprising:
melting a composition including SiO₂ in an amount ranging from 55 mol % to 70 mol %, Al₂O₃ in an amount ranging from 5 mol % to 20 mol %, and MgO in an amount ranging from 29 mol % to 35 mol % to form a molten composition; and
cooling the molten composition.

11. The method of claim 10, wherein a melting temperature in the melting is in a range of from 1400° C. to 1700° C.

12. A method of manufacturing chamber interior parts for a semiconductor manufacturing process, comprising:
melting the plasma-resistant glass of claim 1;
injecting the molten plasma-resistant glass into a mold; and
annealing the injected plasma-resistant glass.

13. The method of claim 12, wherein a melting temperature in the melting the plasma-resistant glass is in a range of from 1400° C. to 1700° C.

14. The method of claim 12, wherein a temperature in the annealing is in a range of from 400° C. to 900° C.
